(19) United States
(12) Patent Application Publication
(10) Pub. No.: US 2005/0161815 A1
(43) Pub. Date: Jul. 28, 2005

(54) Package of a semiconductor device with a flexible wiring substrate and method for the same

(76) Inventors: Joseph Sun, Hsin-Chu City (TW); Kuang-Chih Cheng, Yun-Lin (TW); Ming-Chieh Chen, Hsin-Chu City (TW)

Correspondence Address: LOWE HAUPTMAN GILMAN & BERNER, LLP, Suite 310, 1700 Diagonal Road, Alexandria, VA, 22314, US

(21) Appl. No.: 10/764,469

(22) Filed: Jan. 27, 2004

(51) Int. Cl. H01L 23/48; H01L 21/48

(52) U.S. Cl. 257/738; 438/108

(57) ABSTRACT

A package of a semiconductor device with a flexible wiring substrate and a method thereof are provided. The package of the semiconductor device includes a semiconductor substrate with at least one pad on a surface thereof, a bump bonded to the pad, an adhesive layer on the bump, and a flexible wiring substrate having at least one contact section being electrically connected with the bump by the adhesive layer. The present invention makes the flexible wiring substrate directly conductively attached onto the semiconductor substrate. The package size is shrunk and the cost down can be obtained.

### BACKGROUND OF THE INVENTION

1. Field of the Invention

The present invention relates to a package of a semiconductor device, and more particularly to a package of a semiconductor device electrically connected with a flexible printed circuit board.

2. Description of the Prior Art

Ever increasing industry demand for smaller and smaller electronic packages with low profile, higher area density and increasing number of input/output connections (I/Os) has led to increasing demand for the chip scale package. Use of such packages may be found in small portable products, such as cellular phones, pagers, and the like. Moreover, a flexible printed circuit board (FPC) is widely used in view of the freedom of packaging form and the space saving. A wire bonding is frequently used when a high-density package is required or a package space is limited.

FIG. 1 is a schematic configuration of a known package of an image sensor device incorporated with a handset. The package of the image sensor device has a silicon substrate 101 having at least one pad 105 on a surface thereof and an image sensor device 102, such as CMOS (Complementary Metal-Oxide-Semiconductor) sensor, LCOS (Liquid Crystal-On-Silicon), on the surface. A glass plate 103 is placed above the surface of the silicon substrate 101 having the image sensor device 102. The glass plate 103 is used for preventing the airborn dust or other particles adhered unto the image sensor device 102, causing the image sensor device 102 damage. The glass plate 103 is attached unto the silicon substrate 101 by adhesive material 104. The silicon substrate 101 is placed on a printed circuit board 100, and the pad 105 is connected with an I/O terminal of the printed circuit board 100 via a metal wire 106 by wire bonding. A lens housing 107 enclosing the whole silicon substrate 101 is held on the printed circuit board 100. A lens set 108 is positioned above the glass plate 103 and held by the lens housing 107. A flexible printed circuit board 109 is attached onto the printed circuit board 100. In general, the fingers of the leads of the flexible printed circuit board 109 are bonded to a contact portion of the printed circuit board 100. The flexible printed circuit board 109 is electrically connected to a main board of the handset. The image sensor device 102 captures image signals, and transfers the image signals to electric signals. Then, the electric signals are transmitted to the flexible printed circuit board 109 via an interface, i.e., the printed circuit board 100, and then transmitted to the main board of the handset.

The package of the image sensor device of FIG. 1 is troublesome and bulky. However, the flexible printed circuit board 109 cannot be directly attached unto the silicon substrate 101 due to the configuration of the image sensor device. It is necessary to form a gold bump on the pad 105 of the silicon substrate 101 before the fingers of the leads of the flexible printed circuit board 109 are to be electrically connected with the pad 105. However, the gold bump cannot be electroplated on the pad 105 of the silicon substrate 101 because the glass plate 103 has been covered on the silicon substrate 101. When the silicon substrate 101 is uncovered with the glass plate 103, the image sensor device 102 is easily subjected to damage by the particles during the process of the package, and resulting in a low yield. Therefore, the flexible printed circuit board 109 cannot be directly attached unto the silicon substrate 101 in view of the configuration of the package of the image sensor device.

Accordingly, it is an intention to provide a package method of a semiconductor device, which can overcome the drawbacks of the prior art.

### SUMMARY OF THE INVENTION

It is one objective of the present invention to provide a package of a semiconductor device with a flexible wiring substrate, which directly attaches a flexible printed circuit board unto a semiconductor substrate, so that the package size can be reduced and the cost down can be obtained.

It is another objective of the present invention to provide a package of a semiconductor device with a flexible wiring substrate, which is suitable to a package of an image sensor device.

In order to achieve the above objectives of this invention, the present invention provides a package of a semiconductor device with a flexible wiring substrate and a method thereof. The package of the semiconductor device of the present invention includes a semiconductor substrate with at least one pad on a surface thereof, a bump bonded to the pad, an adhesive layer on the bump, and a flexible wiring substrate having at least one contact section being electrically connected with the bump by the adhesive layer.

The present invention makes the flexible wiring substrate directly electrically connected with the semiconductor device. The shrinkage of the package of the semiconductor device becomes realizable. Moreover, the package method of the present invention is simple and easily completed.

### BRIEF DESCRIPTION OF THE DRAWINGS

The objectives and features of the present invention as well as advantages thereof will become apparent from the following detailed description, considered in conjunction with the accompanying drawings.

FIG. 1 is a schematic configuration of a known package of an image sensor device incorporated with a handset;

FIG. 2 through FIG. 6 is various schematic cross-sectional views respectively corresponding to one stage of a package method of the present invention according to an embodiment; and

FIG. 7 is a process flow of the package method of the present invention corresponding to FIG. 2 through FIG. 6.

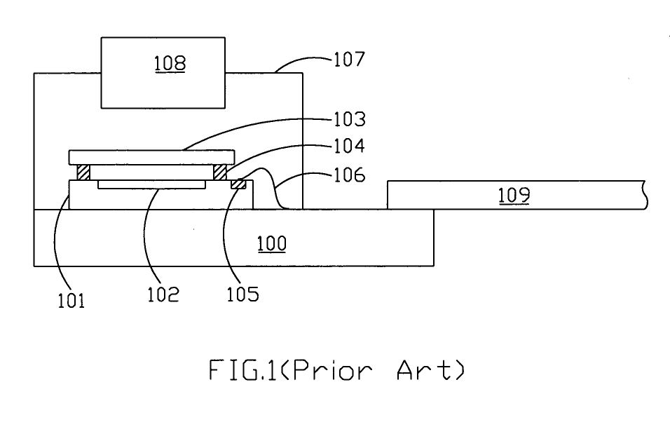

### DESCRIPTION OF THE EMBODIMENTS

The present invention provides a package of a semiconductor device electrically connected with a flexible wiring substrate and a method thereof. The package method of a semiconductor device provided by the present invention is suitable to an application for a wafer covered with a transparent plate.

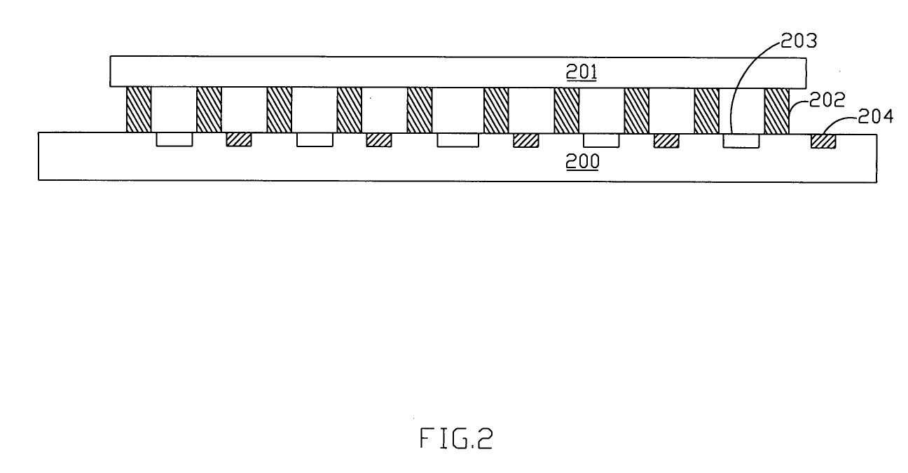

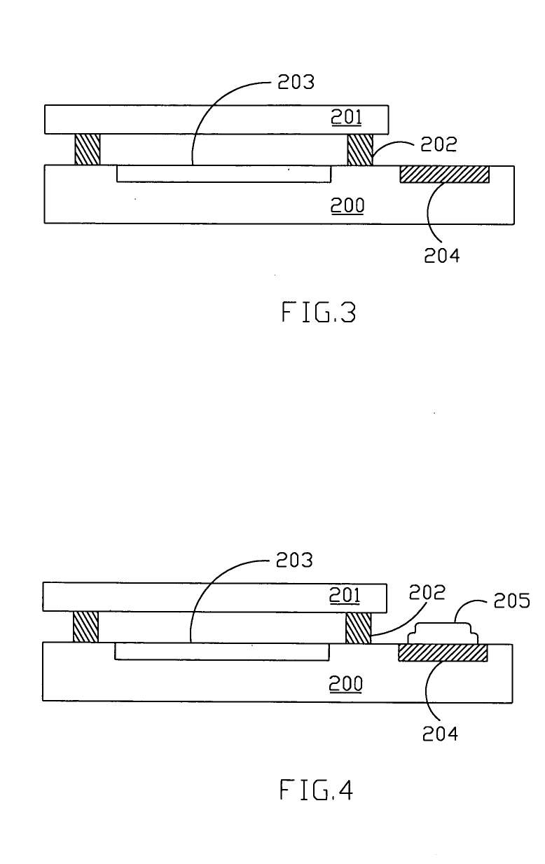

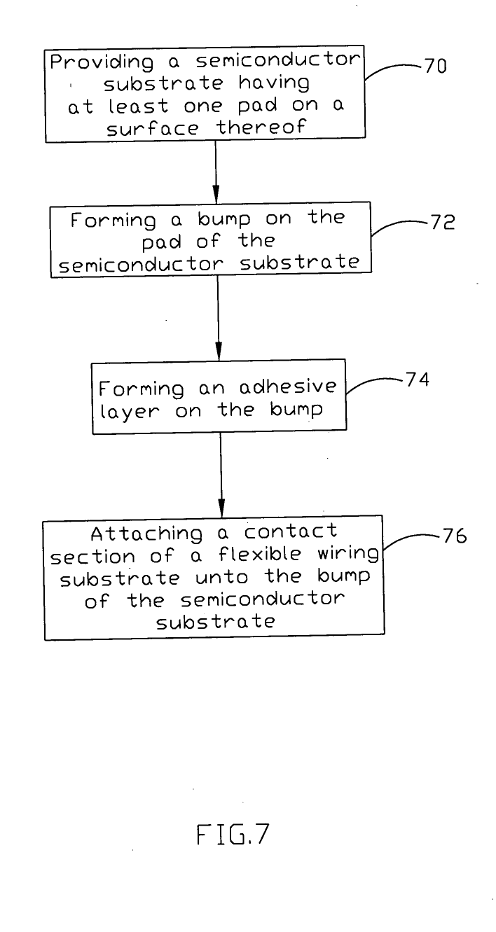

The package of a semiconductor device provided by the present invention and the method thereof will be described in detail in accordance with an embodiment of the present invention accompanying with drawings. FIG. 7 is a process flow of the package method of the present invention in accordance with the embodiment, and FIG. 2 through FIG. 6 is various schematic cross-sectional views, respectively corresponding to each step of the process flow of FIG. 7. Referring to FIG. 7, in step 70, a transparent plate 201 is covered on a surface of a wafer 200 having a plurality of image sensor device 203 and a plurality of pad 204 formed thereon, as shown in FIG. 2. The pad 204 can be an aluminum pad or a copper pad. The image sensor device 203 can be a kind of light-receiving element, such as CMOS sensor, LCOS and the like, and the transparent plate 201 can be a lens or a glass plate. The transparent plate 201 is held on the wafer 200 by adhesive material 202 and used for protecting the image sensor devices 203 from being damaged by particles adhered thereto. The wafer 200 covered with the transparent plate 201 is subjected to a dicing process and divided into chips, also known as “dies”. The dicing process may be accomplished by several means, including a chemical method using acetic acid or fluoroacetic acid, and a scribing method using a diamond cutter. As a consequence, a die 200 having at least one pad 204 on a surface thereof is provided, as shown in FIG. 3. The die 200 will be called “semiconductor substrate” hereinafter. Then, in step 72, a bump is formed on the pad 204 of the semiconductor substrate 200. The bump can be a gold stud bump 205 being formed by a process as the following: a torch rod is placed close a tip of an gold wire, between which a high voltage is applied to generate a spark discharge therebetween, thereby providing a ball at the tip of the gold wire by heat. The ball is then pressed on the pad 204 of the semiconductor substrate 200 by using a bonding tool (capillary), the gold wire being pulled up thereby to provide the gold stud bump 205 on the pad 204, as shown in FIG. 4.

Following, in step 74, an anisotropic conductive paste 206 is applied on the gold stud bump 205 as an adhesive layer, as shown in FIG. 5. The anisotropic conductive paste 206 can be an epoxy-based adhesive resin paste with conductive fillers 207, such as metallic particles, therein. Then, in step 76, a flexible wiring substrate 209, for example, a flexible printed circuit board, having at least one contact section, is provided. The contact section of the flexible wiring substrate 209 is attached unto the anisotropic conductive paste 206 on the gold stud bump 205 to compress the anistropic conductive paste 206 trapped in the interface between the gold stud bump 205 and the contact section of the flexible wiring substrate 209. When the anisptropic conductive paste 206 is compressed, the conductive fillers 207 inside the interface will align themselves and create a conductive path between the semiconductor substrate 200 and the flexible wiring substrate 209. In other words, electrical interconnection between the gold stud bump 205 and the contact section of the flexible wiring substrate 209 is made by conductive fillers' 207 mechanical contact therebetween.

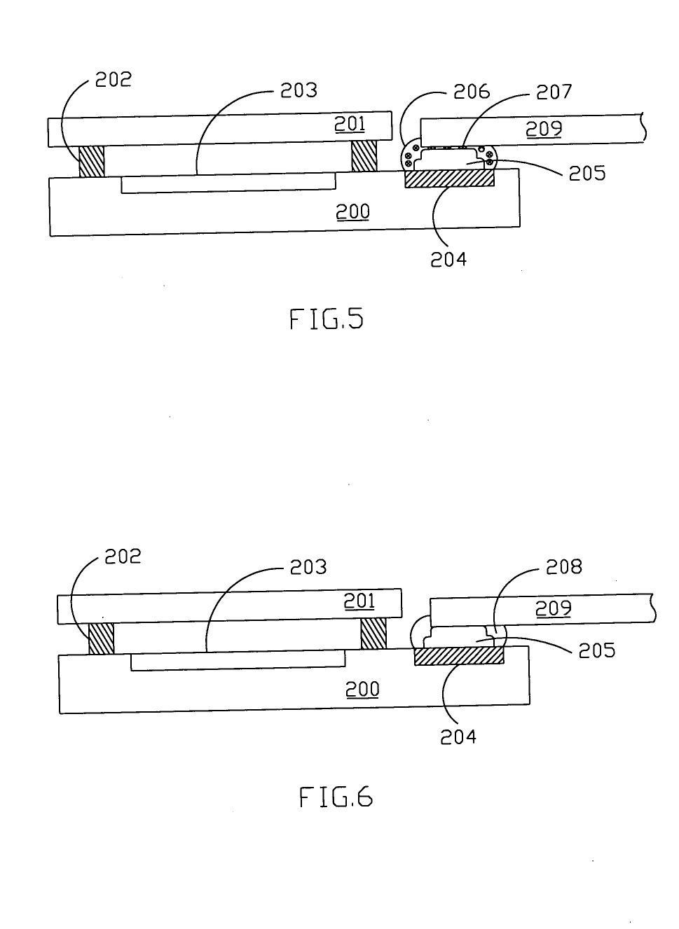

Alternately, as shown in FIG. 6, a non-conductive paste 208 can be applied on the gold stud bump 205 instead of the anisotropic conductive paste 206. The non-conductive paste 208 can be an epoxy adhesive resin. Then, the contact section of the flexible wiring substrate 200 is attached unto the non-conductive paste 208 on the gold stud bump 205 to compress the non-conductive paste 208 trapped in the interface between the gold stud bump 205 and the contact section of the flexible wiring substrate 209. Then, the non-conductive paste 206 trapped in the interface is squeezed out from the interface, and around the gold stud bump 205 and the contact section of the flexible wiring substrate 209. As a consequence, the contact section of the flexible wiring substrate 209 directly contacts with the gold stud bump 205, and both of them are attached together by the non-conductive paste 208 around them.

The present invention makes the flexible wiring substrate 209 directly electrically connected with the semiconductor substrate 200. The shrinkage of the package of the semiconductor device becomes realizable. The package method of the present invention is simple and easily completed. It is possible to attain a purpose of cost down by the present invention.

The embodiments are only used to illustrate the present invention, not intended to limit the scope thereof. Many modifications of the embodiments can be made without departing from the spirit of the present invention.

1. A package of a semiconductor device with a flexible wiring substrate, comprising:
a semiconductor substrate with at least one pad on a surface thereof;
a bump bonded to said pad;
an adhesive layer on said bump; and
a flexible wiring substrate having at least one contact section being electrically connected with said bump by said adhesive layer.

2. The package of claim 1, wherein said bump is stud bump.

3. The package of claim 2, wherein said bump is gold stud bump.

4. The package of claim 1, wherein said adhesive layer includes non-conductive paste.

5. The package of claim 2, wherein said adhesive layer includes non-conductive paste.

6. The package of claim 1, wherein said adhesive layer includes anistropic conductive paste.

7. The package of claim 2, wherein said adhesive layer includes anistropic conductive paste.

8. The package of claim 1, wherein said semiconductor substrate having image sensors on the surface thereof having said pad.

9. The package of claim 8, wherein a transparent plate covered on the surface of said semiconductor substrate having said image sensors.

10. The package of claim 9, wherein said bump is stud bump.

11. The package of claim 10, wherein said adhesive layer includes anistropic conductive paste.

12. The package of claim 10, wherein said adhesive layer includes non-conductive paste.

13. A package method of a semiconductor device with a flexible wiring substrate, comprising:
providing a semiconductor substrate having at least one pad on a surface thereof;
forming a bump on said pad of said semiconductor substrate;
forming an adhesive layer on said bump; and
attaching a flexible wiring substrate unto said semiconductor substrate, wherein said flexible wiring substrate is provided with at least one contact section, and said contact section is electrically connected with said pad by said adhesive layer.

14. The package method of claim 13, wherein said bump is formed by a stud bump process.

15. The package method of claim 14, wherein said bump is formed by a gold stud bump process.

16. The package method of claim 13, wherein said adhesive layer includes non-conductive paste.

17. The package method of claim 14, wherein said adhesive layer includes non-conductive paste.

18. The package method of claim 13, wherein said adhesive layer includes anistropic conductive paste.

19. The package method of claim 14, wherein said adhesive layer includes anistropic conductive paste.

20. The package method of claim 16, wherein said adhesive layer includes epoxy-based non-conductive paste.
